(19) United States
(12) Patent Application Publication
(10) Pub. No.: US 2017/0012149 A1
(43) Pub. Date: Jan. 12, 2017

(54) HIGH EFFICIENCY SINGLE CRYSTAL SILICON SOLAR CELL WITH EPITAXIALLY DEPOSITED SILICON LAYERS WITH DEEP JUNCTION(S)

(71) Applicant: Crystal Solar, Inc., Santa Clara, CA (US)

(72) Inventors: Ruiying Hao, San Jose, CA (US); Tirunelveli S. Ravi, Saratoga, CA (US)

(21) Appl. No.: 15/204,979

(22) Filed: Jul. 7, 2016

Related U.S. Application Data
(60) Provisional application No. 62/189,643, filed on Jul. 7, 2015.

(51) Int. Cl. H01L 31/0352; H01L 31/068; H01L 31/18; H01L 31/0288

(52) U.S. Cl. CPC H01L 31/03529; H01L 31/0288; H01L 31/0684; H01L 31/1804

(57) ABSTRACT

Embodiments of the present invention may include single crystal silicon solar cell structures with epitaxially deposited silicon device layers with deep junction(s). In some embodiments, the single crystal silicon solar cell structures may comprise a moderately doped, thick (greater than 10 microns), epitaxially deposited silicon emitter layer. In some embodiments, the single crystal silicon solar cell structures may comprise moderately doped, thick (greater than 10 microns), epitaxially deposited FSF layers. The moderate doping reduces electron-hole recombination within the FSF and emitter layers and causes smaller bandgap narrowing and reduced Auger recombination compared to prior art devices which typically have more heavily doped layers, and the thicker FSF and emitter layers than typically used in prior art devices assist in having a desirable sheet resistance for the solar cell front and back surface, as measured prior to front side and back side metallization.

### CROSS-REFERENCE TO RELATED APPLICATIONS

This application claims the benefit of U.S. Provisional Application No. 62/189,643 filed Jul. 7, 2015, incorporated by reference in its entirety herein.

### FIELD OF THE INVENTION

The present invention relates generally to solar cells, and more particularly, although not exclusively, to single crystal silicon solar cells with epitaxially deposited silicon device layers with deep junction(s), including, in some embodiments a moderately doped n-type silicon FSF layer, and in some embodiments a moderately doped p-type silicon emitter layer.

### BACKGROUND

There is a need for solar cells with higher efficiency and more efficient manufacturing processes for the same.

### SUMMARY OF THE INVENTION

Some embodiments of the present invention may include single crystal silicon solar cell structures with epitaxially deposited silicon device layers with deep junction(s). In some embodiments, the single crystal silicon solar cell structures may comprise a moderately doped, thick (greater than 10 microns), epitaxially deposited silicon emitter layer. In some embodiments, the single crystal silicon solar cell structures may comprise moderately doped, thick (greater than 10 microns), epitaxially deposited FSF layers. The moderate doping reduces electron-hole recombination within the FSF and emitter layers and causes smaller bandgap narrowing and reduced Auger recombination compared to prior art devices which typically have more heavily doped layers, and the thicker FSF and emitter layers than typically used in prior art devices assist in having a desirable sheet resistance for the solar cell front and back surface, as measured prior to front side and back side metallization.

According to embodiments, a silicon solar cell structure may comprise: an n-type single crystal epitaxial silicon layer, the n-type single crystal epitaxial silicon layer having an n-type dopant concentration in the range of intrinsic to 5.0E15/cm³, and in embodiments intrinsic to 1.0E16/cm³, endpoints inclusive, the n-type single crystal epitaxial silicon layer having first and second surfaces; and a front surface field (FSF) on the second surface of the n-type single crystal epitaxial silicon layer, the FSF comprising an as-deposited n-type single crystal epitaxial silicon FSF layer contacting the second surface of the n-type single crystal epitaxial silicon layer, the as-deposited n-type single crystal epitaxial silicon FSF layer having an n-type dopant concentration in the range of 5.0E16/cm³ to 5.0E18/cm³, endpoints inclusive, the as-deposited n-type single crystal epitaxial silicon FSF layer having an average thickness (indicated by “z” in FIG. 2) of greater than 10 microns; and a p⁺ emitter on the first surface of the n-type single crystal epitaxial silicon layer.

According to embodiments, a silicon solar cell structure may comprise: an n-type single crystal epitaxial silicon layer, the n-type single crystal epitaxial silicon layer having an n-type dopant concentration in the range of intrinsic to 5.0E15/cm³, and in embodiments intrinsic to 1.0E16/cm³, endpoints inclusive, the n-type single crystal epitaxial silicon layer having first and second surfaces; and a front surface field (FSF) on the second surface of the n-type single crystal epitaxial silicon layer, the FSF comprising a diffused layer having an n-type dopant concentration in the range of 5.0E16/cm³ to 5.0E18/cm³, endpoints inclusive; and a p⁺ emitter on the first surface of the n-type single crystal epitaxial silicon layer, the p^{H} emitter comprising an as-deposited p-type single crystal epitaxial silicon layer with a p-type dopant concentration in the range of 1.0E16/cm³ to 5.0E18/cm³, endpoints inclusive, the p⁺ emitter further comprising an aluminum-doped p-type single crystal epitaxial silicon layer separated from the first surface by the as-deposited p-type single crystal epitaxial silicon layer, the as-deposited p-type single crystal epitaxial silicon layer having an average thickness of greater than 10 microns.

According to embodiments, a silicon solar cell structure may comprise: an n-type single crystal epitaxial silicon layer, the n-type single crystal epitaxial silicon layer having an n-type dopant concentration in the range of intrinsic to 5.0E15/cm³, and in embodiments intrinsic to 1.0E16/cm³, endpoints inclusive, the n-type single crystal epitaxial silicon layer having first and second surfaces; and a front surface field (FSF) on the second surface of the n-type single crystal epitaxial silicon layer, the FSF comprising an as-deposited n-type single crystal epitaxial silicon FSF layer contacting the second surface of the n-type single crystal epitaxial silicon layer, the as-deposited n-type single crystal epitaxial silicon FSF layer having an n-type dopant concentration in the range of 5.0E16/cm³ to 5.0E18/cm³, endpoints inclusive, the as-deposited n-type single crystal epitaxial silicon FSF layer having an average thickness (indicated by “z” in FIG. 4) of greater than 10 microns; and a p⁺ emitter on the first surface of the n-type single crystal epitaxial silicon layer.

According to embodiments, a silicon solar cell structure may comprise: an n-type single crystal epitaxial silicon layer, the n-type single crystal epitaxial silicon layer having an n-type dopant concentration in the range of intrinsic to 5.0E15/cm³, and in embodiments intrinsic to 1.0E16/cm³, endpoints inclusive, the n-type single crystal epitaxial silicon layer having first and second surfaces; and a front surface field (FSF) on the second surface of the n-type single crystal epitaxial silicon layer, the FSF comprising a diffused layer having an n-type dopant concentration in the range of 5.0E16/cm³ to 5.0E18/cm³, endpoints inclusive; and a p⁺ emitter on the first surface of the n-type single crystal epitaxial silicon layer, the p⁺ emitter comprising as-deposited p-type single crystal epitaxial silicon contacting the first surface of the n-type single crystal epitaxial silicon layer, the as-deposited p-type single crystal epitaxial silicon having a p-type dopant concentration in the range of 1.0E16/cm³ to 5.0E18/cm³, endpoints inclusive, the p⁺ emitter further comprising a plurality of aluminum-doped p-type single crystal epitaxial silicon point contact regions, the p⁺ emitter having an average thickness (indicated by “y” in FIG. 3) of greater than 10 microns.

According to embodiments, a silicon solar cell structure may comprise: a first n-type single crystal epitaxial silicon layer, the first n-type single crystal epitaxial silicon layer having an n-type dopant concentration in the range of intrinsic to 5.0E15/cm³, and in embodiments intrinsic to 1.0E16/cm³, endpoints inclusive, the first n-type single crystal epitaxial silicon layer having first and second surfaces; and a front surface field (FSF) on the second surface of the first n-type single crystal epitaxial silicon layer, the FSF comprising a second n-type single crystal epitaxial silicon layer contacting the second surface of the first n-type single crystal epitaxial silicon layer, the second n-type single crystal epitaxial silicon layer having an n-type dopant concentration in the range of 5.0E16/cm³ to 5.0E18/cm³, endpoints inclusive, the FSF having a thickness in the range of greater than or equal to 10 microns to less than or equal to 60 microns.

According to embodiments, a silicon solar cell structure may comprise: a first n-type single crystal epitaxial silicon layer, the first n-type single crystal epitaxial silicon layer having an n-type dopant concentration in the range of intrinsic to 5.0E15/cm³, and in embodiments intrinsic to 1.0E16/cm³, endpoints inclusive, the first n-type single crystal epitaxial silicon layer having first and second surfaces; and a p⁺ emitter on the first surface of the n-type single crystal epitaxial silicon layer, the p⁺ emitter comprising an epitaxially deposited p-type single crystal epitaxial silicon layer with a p-type dopant concentration in the range of 1.0E16/cm³ to 5.0E18/cm³, endpoints inclusive, the epitaxially deposited p-type single crystal epitaxial silicon layer having an average thickness in the range of greater than 10 microns to less than 70 microns.

According to embodiments, a method of fabricating a single crystal silicon solar cell structure may comprise: epitaxially depositing on a reusable single crystal silicon wafer a first n-type single crystal silicon layer having a thickness in the range of greater than 10 microns to less than 60 microns, the first n-type silicon layer having an n-type dopant concentration in the range of 5.0E16/cm³ to 5.0E18/cm³; epitaxially depositing on the first n-type single crystal silicon layer a second n-type single crystal silicon layer, the second n-type single crystal silicon layer having an n-type dopant concentration in the range of intrinsic to 5.0E15/cm³, and in embodiments intrinsic to 1.0E16/cm³, endpoints inclusive; and separating the single crystal silicon solar cell structure from the reusable single crystal silicon wafer.

According to embodiments, a method of fabricating a single crystal silicon solar cell structure may comprise: epitaxially depositing on a reusable single crystal silicon wafer a first n-type single crystal silicon layer, the first n-type single crystal silicon layer having an n-type dopant concentration in the range of intrinsic to 5.0E15/cm³, and in embodiments intrinsic to 1.0E16/cm³, endpoints inclusive; epitaxially depositing on the first n-type single crystal silicon layer, a p-type single crystal silicon layer having a p-type dopant concentration in the range of 1.0E16/cm³ to 5.0E18/cm³, endpoints inclusive, the p-type single crystal silicon layer having an average thickness in the range of greater than 10 microns to less than 70 microns; and separating the single crystal silicon solar cell structure from the reusable single crystal silicon wafer.

According to embodiments, a method of fabricating a silicon solar cell structure may comprise: providing an n-type silicon wafer, the wafer comprising: a first n-type single crystal epitaxial silicon layer, the first n-type single crystal epitaxial silicon layer having an n-type dopant concentration in the range of intrinsic to 5.0E15/cm³, and in embodiments intrinsic to 1.0E16/cm³ , endpoints inclusive, the first n-type single crystal epitaxial silicon layer having first and second surfaces; and a front surface field (FSF) on the second surface of the first n-type single crystal epitaxial silicon layer, the FSF comprising a second n-type single crystal epitaxial silicon layer contacting the second surface of the first n-type single crystal epitaxial silicon layer, the second n-type single crystal epitaxial silicon layer having an n-type dopant concentration in the range of 5.0E16/cm³ to 5.0E18/cm³, endpoints inclusive, the FSF having a thickness in the range of greater than 10 microns to less than 60 microns; and forming a p⁺ emitter on the first surface of the first n-type single crystal epitaxial silicon layer.

According to embodiments, a method of fabricating a silicon solar cell structure may comprise: providing a silicon wafer, the wafer comprising: a first n-type single crystal epitaxial silicon layer, the first n-type single crystal epitaxial silicon layer having an n-type dopant concentration in the range of intrinsic to 5.0E15/cm³, and in embodiments intrinsic to 1.0E16/cm³, endpoints inclusive, the first n-type single crystal epitaxial silicon layer having first and second surfaces; a front surface field (FSF) on the second surface of the first n-type single crystal epitaxial silicon layer, the FSF comprising a second n-type single crystal epitaxial silicon layer contacting the second surface of the first n-type single crystal epitaxial silicon layer, the second n-type single crystal epitaxial silicon layer having an n-type dopant concentration in the range of 5.0E16/cm³ to 5.0E18/cm³, endpoints inclusive, the FSF having a thickness in the range of greater than 10 microns to less than 60 microns; and a p⁺ emitter on the first surface of the first n-type single crystal epitaxial silicon layer, the p⁺ emitter comprising an epitaxially deposited p-type single crystal epitaxial silicon layer with a p-type dopant concentration in the range of 1.0E16/cm³ to 5.0E18/cm³, endpoints inclusive, the epitaxially deposited p-type single crystal epitaxial silicon layer having an average thickness in the range of greater than 10 microns to less than 70 microns; and forming n⁺⁺ areas on the surface of the FSF for making ohmic contact between the FSF and metal contact structures.

According to embodiments, a method of fabricating a silicon solar cell structure may comprise: providing a silicon wafer, the wafer comprising: a first n-type single crystal epitaxial silicon layer, the first n-type single crystal epitaxial silicon layer having an n-type dopant concentration in the range of intrinsic to 5.0E15/cm³, and in embodiments intrinsic to 1.0E16/cm³, endpoints inclusive, the first n-type single crystal epitaxial silicon layer having first and second surfaces; and a p⁺ emitter on the first surface of the first n-type single crystal epitaxial silicon layer, the p⁺ emitter comprising an epitaxially deposited p-type single crystal epitaxial silicon layer with a p-type dopant concentration in the range of 1.0E16/cm³ to 5.0E18/cm³, endpoints inclusive, the epitaxially deposited p-type single crystal epitaxial silicon layer having an average thickness in the range of greater than 10 microns to less than 70 microns; and forming a front surface field (FSF) on the second surface of the first n-type single crystal epitaxial silicon layer.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIGS. 1 & 2 are cross-sectional views of a representation of a full aluminum BSF solar cell based on epitaxially-grown, silicon n-p⁺ and n⁺n-p⁺ structures, respectively, according to some embodiments of the present invention;

FIGS. 3 & 4 are cross-sectional views of a representation of a PERC solar cell based on epitaxially-grown, silicon n-p⁺ and n⁺n-p⁺ structures, respectively, according to some embodiments of the present invention;

FIG. 5 is a cross-sectional view of a representation of a silicon n-p+ structure epitaxially grown on a reusable single crystal silicon substrate, according to some embodiments of the present invention; and

FIG. 6 is a cross-sectional view of a representation of a silicon n⁺-n-p⁺ structure epitaxially grown on a reusable single crystal silicon substrate, according to some embodiments of the present invention.

### DETAILED DESCRIPTION

Embodiments of the present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration. Note that for ease of illustration the drawings provided herewith are not drawn to scale—some layers appearing much larger relative to other layers than they actually are.

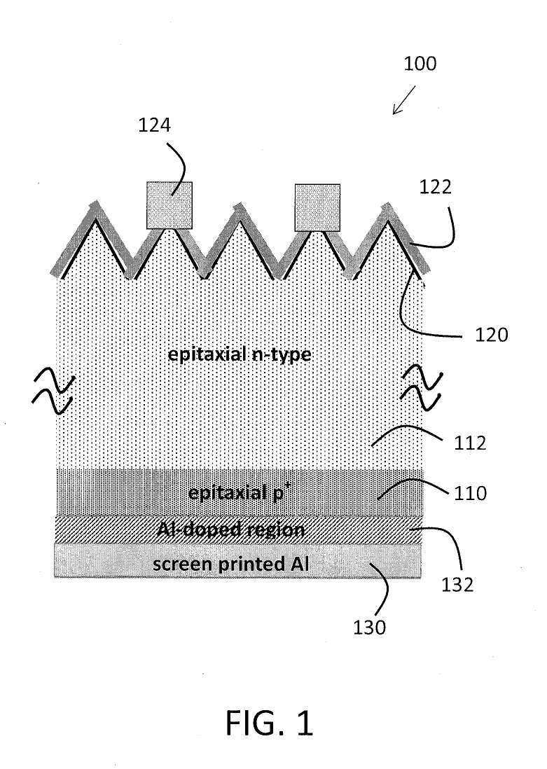

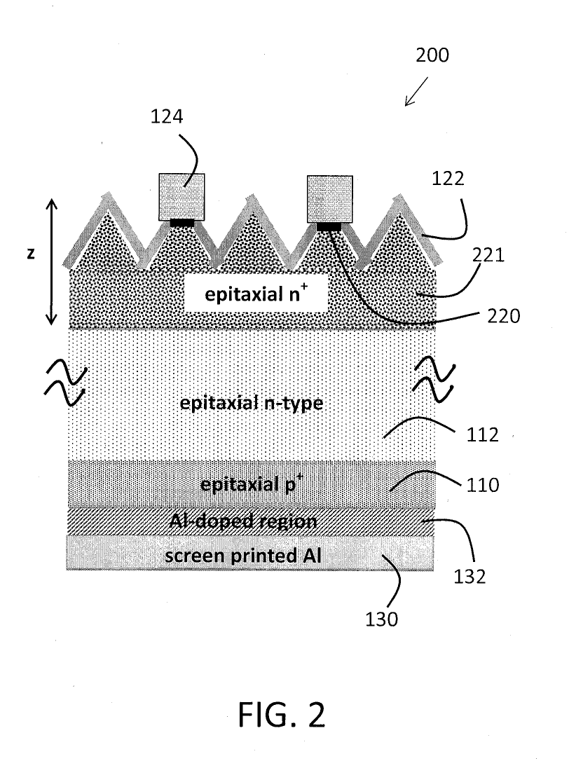

To overcome manufacturing challenges with prior art designs of high efficiency single crystal n-type silicon solar cells, it is proposed that an n-p+ sandwich structure or an n+-n-p+ sandwich structure including a moderately doped FSF is used; the structures may be grown in-situ by epitaxial deposition on a reusable substrate. Examples of proposed solar cell structures are shown in FIGS. 1-4—full Al BSF (Back Surface Field) and PERC (Passivated Emitter Rear Cell) cells, respectively. The n-p+ and n+-n-p+ sandwich structures are two types of kerfless wafer that can be used as a “drop in replacement” for current monocrystalline wafers in p-type single crystal silicon solar cells; the total thickness of the n-p+ and n+-n-p+ sandwich structure in embodiments is in the range of approximately 100 μm to 200 μm, and in further embodiments is in the range of approximately 30 μm to 100 μm.

FIG. 1 shows a full aluminum BSF solar cell structure 100, according to some embodiments, the structure comprising an epitaxial single crystal p⁺ silicon emitter layer 110 formed on an epitaxial single crystal n-type silicon layer 112 with a texture etched front surface. On the back side of the structure there is a screen printed aluminum layer 130 with an aluminum-doped silicon layer 132 between the layers 130 and 110. On the front side of the structure there is an n⁺ FSF 120 (formed by a POCl₃ process for example) and on the FSF there is a passivation and antireflection layer 122 (a layer of silicon nitride, for example) and front side contacts 124 (formed by screen printing Ag paste and firing, for example).

FIG. 2 shows a full aluminum BSF solar cell structure 200, according to some embodiments. The structure of FIG. 2 is the same as the structure of FIG. 1, except for an epitaxially deposited n⁺ FSF 221 of thickness z, and an n⁺⁺ layer 220 (formed by a POCl₃ process for example, at the position of the front side contacts 124) in the n⁺ FSF 221.

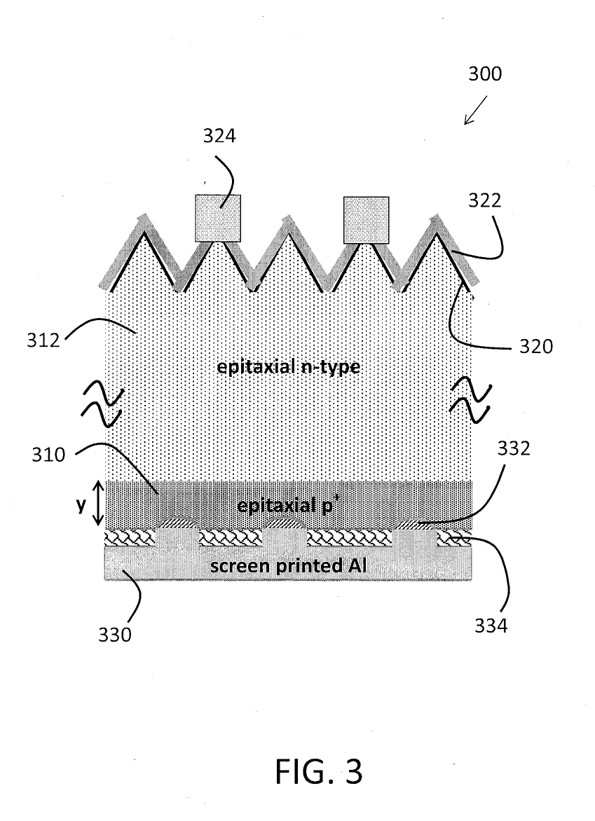

FIG. 3 shows a PERC solar cell structure 300, according to some embodiments, the structure comprising an epitaxial single crystal p⁺ silicon emitter layer 310 of average thickness y formed on an epitaxial single crystal n-type silicon layer 312 with a texture etched front surface. On the back side of the structure there is a screen printed aluminum layer 330 with locally aluminum-doped silicon regions 332 (formed by firing of screen printed aluminum back side contact, for example), and a stack of dielectric layers 334, in which there are apertures filled with back side aluminum (part of layer 330). On the front side of the structure there is an n⁺ FSF 320 (formed by a POCl₃ process, for example) and on the FSF there is a passivation and antireflection layer 322 (a layer of silicon nitride, for example) and front side contacts 324 (formed by screen printing Ag paste and firing, for example).

FIG. 4 shows a PERC solar cell structure 400, according to some embodiments. The structure of FIG. 4 is the same as the structure of FIG. 3, except for an epitaxially deposited n⁺ FSF 421 of thickness z, and an n⁺⁺ layer 420 (formed by a POCl₃ process for example, at the position of the front side contacts 324) in the n⁺ FSF 421.

Examples of process flows to make solar cells such as shown in FIGS. 1-4 are provided below and it is expected that these processes may be incorporated in to a standard p-type silicon solar cell manufacturing line.

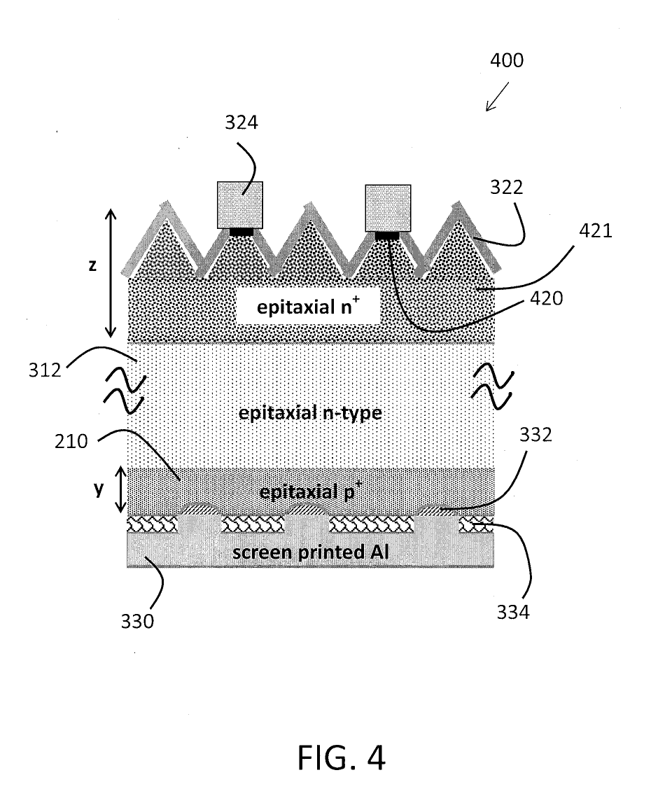

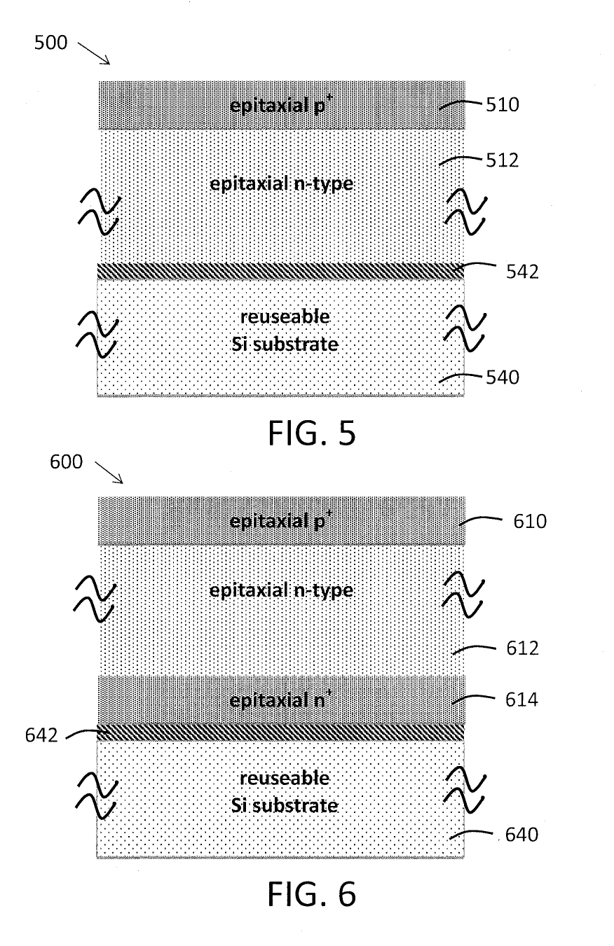

(1) a thin silicon wafer is epitaxially deposited on a reusable single crystal silicon substrate; the wafer may comprise an intrinsic to 5.0E15/cm³, and in embodiments intrinsic to 1.0E16/cm³, n-type silicon layer greater than 10 microns thick, in embodiments greater than 20 microns thick, in further embodiments between 20 and 200 microns thick, and a 1E16/cm³ to 5 E18/cm³, and in embodiments 5 E16/cm³ to 1 E18/cm³, p⁺ type silicon layer between 10 and 70 microns thick formed by in-situ epitaxial deposition of one layer followed by the other in an epitaxial reactor, for example, as described in U.S. Patent Application Publication Nos. 2013/0032084, 2010/0215872 and 2010/0263587, all incorporated in their entirety by reference herein. These publications describe epitaxial reactors which are a low cost, high throughput tool for epitaxial single crystal silicon deposition by chemical vapor deposition (CVD) which can be utilized for the epitaxial deposition processes described herein. Moreover, U.S. Patent Application Publication No. 2013/0032084 describes fabrication of silicon wafers by epitaxial growth—for some embodiments a thin silicon wafer is epitaxially grown with a built-in p⁺-n junction as described herein. See FIG. 5, which shows a p⁻-n stack comprising an epitaxial single crystal silicon p⁺ layer 510 on an epitaxial single crystal n-type layer 512 formed on a porous silicon separation layer 542 on a reusable single crystal silicon substrate 540.

(2) the n-p⁺ wafer is separated from the reusable silicon substrate by a process such as described in U.S. Patent Application Publication Nos. 2013/020111, 2013/0032084, 2010/0215872 and 2010/0263587.

(3) the n-p⁺ wafer is texture etched on one surface or both surfaces (typically the surface facing sunlight) using an etch such as an alkaline wet chemical etch (solutions containing potassium hydroxide (KOH) and isopropyl alcohol (IPA), for example), forming a textured surface.

(4) both sides of the n-p⁺ wafer are then subjected to a wafer clean followed by n++ layer FSF formation, e.g. by phosphorus diffusion.

In embodiments, the n⁺ layer may be grown epitaxially, using a process such as described as follows:

(1) a thin silicon wafer is epitaxially deposited on a reusable single crystal silicon substrate; the wafer may comprise a 5E16/cm³ to 5E18/cm³ n⁺ type silicon layer greater than 10 microns thick, in embodiments between 10 and 60 microns, an intrinsic to 5.0E15/cm³, and in embodiments intrinsic to 1.0E16/cm³, n-type silicon layer greater than 10 microns thick, in embodiments greater than 20 microns thick, in further embodiments between 20 and 200 microns thick, and a 1E16/cm³ to 5E18/cm³, and in embodiments 5E16/cm³ to 1E18/cm³, p⁺ type silicon layer between 10 and 70 microns thick formed by in-situ epitaxial deposition of one layer followed by the other in an epitaxial reactor, for example, as described in U.S. Patent Application Publication Nos. 2013/0032084, 2010/0215872 and 2010/0263587, all incorporated in their entirety by reference herein. These publications describe epitaxial reactors which are a low cost, high throughput tool for single crystal epitaxial silicon deposition by chemical vapor deposition (CVD) which can be utilized for the epitaxial deposition processes described herein. Moreover, U.S. Patent Application Publication No. 2013/0032084 describes fabrication of single crystal silicon wafers by epitaxial growth—for some embodiments a thin single crystal silicon wafer is epitaxially grown with built-in p⁺-n-n⁺ junctions as described herein. See FIG. 6, which shows a p⁺-n-n⁺ stack comprising an epitaxial single crystal silicon p⁺ layer 610 on an epitaxial single crystal n-type layer 612 on an epitaxial single crystal silicon n⁺ layer 614 formed on a porous silicon separation layer 642 on a reusable single crystal silicon substrate 640.

(2) the n⁺-n-p⁺ wafer is separated from the reusable silicon substrate by a process such as described in U.S. Patent Application Publication Nos. 2013/020111, 2013/0032084, 2010/0215872 and 2010/0263587.

(3) the n⁺-n-p⁺ wafer is texture etched on one surface or both surfaces (typically the surface facing sunlight) using an etch such as an alkaline wet chemical etch (solutions containing potassium hydroxide (KOH) and isopropyl alcohol (IPA), for example), forming a textured surface.

(4) both sides of the n⁺-n-p⁺ wafer are then subjected to a wafer clean followed by a selective n⁺⁺ region formation process, e.g. ion implantation or screen printing phosphorus diffusion paste on the n-type surface and driving the dopant into the n-type layer (by thermal diffusion) for ohmic metal contact formation and also for contact passivation. Alternatively, both sides of the n⁺-n-p⁺ wafer are then subjected to a wafer clean followed by an n⁺⁺ formation, e.g. phosphorus diffusion. Then a chemically stable paste is printed on the emitter side and on top of the region where metal contact will be made. The n⁺⁺ layer in the unmasked regions are removed in an etch process. Finally the pasted is cleaned off,

Alternatively, at step (3) the n⁺-n-p⁺ wafer is then subjected to an n⁺⁺ layer formation, e.g. phosphorus diffusion, and at step (4) a KOH stable paste is printed on the n⁺ Si side and on top of the region where metal contact will be made, the n⁺-n-p⁺ wafer is texture etched on one surface or both surfaces (typically the surface facing sunlight) using an etch such as an alkaline wet chemical etch (solutions containing potassium hydroxide (KOH) and isopropyl alcohol (IPA), for example), forming a textured surface. After texturing, the paste is cleaned off.

(5) both sides of the n⁺-n-p⁺ wafer are then subjected to a wafer clean.

To fabricate a full Al-BSF cell starting with an n-p⁺ wafer with diffused n⁻⁺ emitter, the following process may be followed:

(1) etch the emitter on wafer's edges and on the p⁺ Si side, or planarize the p⁺ side if needed; this step is not needed if the texturing is only of the front surface and the emitter is only formed on the front surface.

(2) grow or deposit passivation and antireflection layers, such as SiO₂ and SiNₓ, on the n type emitter side of the n-p⁺ wafer.

(3) screen print Ag paste to form fingers and busbars on the emitter side;

(4) screen print Al paste, for forming aluminum fired-through contacts, and screen print Ag busbars on the p⁺-type side. In further embodiments, blanket aluminum may be sputtered on the p-type surface instead of forming busbars.

(5) co-fire contacts.

(6) measure solar cell device operational characteristics, and bin according to application requirements.

Note that to fabricate a full Al-BSF cell starting with an n⁺-n-p⁺ wafer with diffused n⁺⁺ front side contacts, the following adjustments to the process may be needed: in the front metal formation step screen print Ag paste to form fingers and busbars on the coated n+ surface, where the fingers and busbars are aligned to, and make electrical contact with, the n⁺⁺ regions.

To fabricate a PERC cell starting with an n-p⁺ wafer with diffused n⁺⁺ FSF, the following process may be followed:

(1) etch the emitter on wafer's edges and on the p⁺ Si side, or planarize the p⁺ side if needed; this step is not needed if the texturing is only of the front surface and the emitter is only formed on the front surface.

(2) grow or deposit passivation layers, such as SiO₂, SiN, or Al₂O₃, on both sides of the n-p⁺ wafer; the dielectric layer(s) on the emitter surface also behave(s) as an antireflection coating.

(3) open up windows in the passivation layers on the p⁺ type side of the wafer where the metal contacts to the p⁺-type layer will be formed—this may be achieved using a laser.

(4) screen print Ag paste to form fingers and busbars on the emitter side;

(5) screen print Al paste, for forming aluminum fired-through contacts, and screen print Ag busbars on the p⁺-type side. In further embodiments, blanket aluminum may be sputtered on the p-type surface instead of forming busbars.

(6) co-fire contacts.

(7) measure solar cell device operational characteristics, and bin according to application requirements.

Note that to fabricate a PERC cell starting with an n⁺-n-p⁺ wafer with diffused n⁺⁺ front side contacts, the following adjustments to the process may be needed: in the front metal formation step screen print Ag paste to form fingers and busbars on the coated n+ surface, where the fingers and busbars are aligned to, and make electrical contact with, the n⁺⁺ regions.

Furthermore, variations on the above process flows may include alternative materials and deposition methods for the front-side and back-side electrical contacts. For example, front and back contact grids may be formed by depositing metal paste and firing, the front and/or back contact grids may also be formed by other techniques including electroplating of metals and alloys, such as copper (using a suitable barrier metallurgy such as Ni followed by copper plate-up).

The advantages of a solar cell with a structure and fabrication process such as described above with reference to FIGS. 1-6 may include one or more of the following:

(a) Reduced surface recombination velocity due to a more effective surface passivation on lightly doped p⁺ or n⁺ surface layer (a limitation of traditional diffusion or ion implantation); for higher V_{oc} to be achieved; beneficial properties to various cell structures, e.g. p-type full Al BSF cell, p-type PERC cell, HIT cell, n-type cell, etc.

(b) Lower sheet resistance, which provides: better control of doping concentration and thickness compared to traditional diffusion and ion implantation; lower sheet resistance leading to fewer Ag fingers and thus lower Ag consumption.

(c) Epitaxially-deposited wafers as described above can be processed in a standard p-type silicon solar cell line.

(d) There is no appreciable Light Induced Degradation (LID) due to the low oxygen level in the p-type epitaxially-deposited single crystal silicon, and no LID for n-type epitaxially-deposited silicon, when an epitaxially deposited emitter is used.

(e) POCl₃ (phosphorus doping) or BBr₃ (boron doping) diffusion processes are not essential, since emitter formation can be by epitaxial deposition.

Furthermore, the significant improvement in device performance that can be achieved using the teaching and principles of the present invention are evident from the recent publication of test results for devices of the type shown in FIG. 3, for example, and described above, the devices achieving record breaking solar cell efficiency of 22.5 percent for nPERT silicon solar cells formed on kerfless epitaxial wafers. See “Imec and Crystal Solar Demonstrate 22.5 Percent nPERT Si Solar Cells on Kerfless Epitaxial Wafers” PRNewswire Apr. 14, 2016, available at http://www.prnewswire.com/news-releases/imec-and-crystal-solar-demonstrate-225-percent-npert-si-solar-cells-on-kerfless-epitaxial-wafers-300251309.html, last viewed on Jul. 7, 2016; Kerfless Epitaxial Mono Crystalline Si Wafers With Built-in Junction And From Reused Substrates For High Efficiency PERx Cells, Ruiying Hao et al., 43^{rd} IEEE Photovoltaic Specialists Conference, Portland, Oregon, Jun. 5-9, 2016.

Although the present invention has been described with reference to epitaxially fabricated single crystal silicon n-p⁺ sandwich structures, and epitaxially fabricated single crystal silicon n⁺⁻ n-p⁺ sandwich structures including a moderately doped FSF, further embodiments include solar cell structures with epitaxially fabricated single crystal silicon n⁺-n sandwich structures including a moderately doped FSF. Solar cell structures including these epitaxially fabricated single crystal silicon n⁺-n sandwich structures with a moderately doped FSF may further include p⁺ emitters formed by, for example, diffusion, ion implantation, or deposition (of amorphous silicon, for example).

Some examples of full aluminum back contact cell structures with a diffused FSF are provided below. See FIG. 1.

According to some embodiments, a silicon solar cell structure may comprise: an n-type single crystal epitaxial silicon layer, the n-type single crystal epitaxial silicon layer having an n-type dopant concentration in the range of intrinsic to 1.0E16/cm³, endpoints inclusive, the n-type single crystal epitaxial silicon layer having first and second surfaces; and a front surface field (FSF) on the second surface of the n-type single crystal epitaxial silicon layer, the FSF comprising a diffused layer having an n-type dopant concentration in the range of 1.0E17/cm³ to 5.0E20/cm³, endpoints inclusive; and a p⁺ emitter on the first surface of the n-type single crystal epitaxial silicon layer, the p⁺ emitter comprising an as-deposited p-type single crystal epitaxial silicon layer with a p-type dopant concentration in the range of 1.0E16/cm³ to 5.0E18/cm³, endpoints inclusive, the p⁺ emitter further comprising an aluminum-doped p-type single crystal epitaxial silicon layer separated from the first surface by the as-deposited p-type single crystal epitaxial silicon layer, the as-deposited p-type single crystal epitaxial silicon layer having an average thickness of greater than 10 microns. Furthermore, wherein the FSF may be texture etched on a front surface. Furthermore, wherein the diffused layer may have a thickness in the range of 0 to 5 microns. Furthermore, wherein the as-deposited p-type single crystal epitaxial silicon layer may have a uniform dopant concentration in the range of 5.0E16/cm³ to 5.0E18/cm³, endpoints inclusive. Furthermore, wherein the as-deposited p-type single crystal epitaxial silicon layer may have a thickness in the range of 10 microns to 60 microns, endpoints inclusive. Furthermore, wherein the as-deposited p-type single crystal epitaxial silicon layer may have a thickness in the range of 15 microns to 55 microns, endpoints inclusive. Furthermore, wherein the silicon solar cell may be bifacial. Furthermore, wherein the silicon solar cell may have textured front and back surfaces.

Some examples of full aluminum back contact cell structures with an epitaxially deposited FSF are provided below. See FIG. 2.

According to some embodiments, a silicon solar cell structure may comprise: an n-type single crystal epitaxial silicon layer, the n-type single crystal epitaxial silicon layer having an n-type dopant concentration in the range of intrinsic to 5.0E15/cm³, endpoints inclusive, the n-type single crystal epitaxial silicon layer having first and second surfaces; and a front surface field (FSF) on the second surface of the n-type single crystal epitaxial silicon layer, the FSF comprising an as-deposited n-type single crystal epitaxial silicon FSF layer contacting the second surface of the n-type single crystal epitaxial silicon layer, the as-deposited n-type single crystal epitaxial silicon FSF layer having an n-type dopant concentration in the range of 5.0E16/cm³ to 5.0E18/cm³, endpoints inclusive, the as-deposited n-type single crystal epitaxial silicon FSF layer having an average thickness (indicated by “z” in FIG. 2) of greater than 10 microns; and a p⁺ emitter on the first surface of the n-type single crystal epitaxial silicon layer. Furthermore, wherein the p⁺ emitter may comprise an as-deposited p-type single crystal epitaxial silicon layer with a p-type dopant concentration in the range of 1.0E16/cm³ to 5.0E18/cm³, endpoints inclusive, the p⁺ emitter further comprising an aluminum-doped p-type single crystal epitaxial silicon layer separated from the first surface by the as-deposited p-type single crystal epitaxial silicon layer, the as-deposited p-type single crystal epitaxial silicon layer having an average thickness of greater than 10 microns, and furthermore, wherein the as-deposited p-type single crystal epitaxial silicon layer may have a uniform dopant concentration in the range of 5.0E16/cm³ to 5.0E18/cm³, endpoints inclusive, or wherein the as-deposited p-type single crystal epitaxial silicon layer may have a thickness in the range of 10 microns to 60 microns, endpoints inclusive, or wherein the as-deposited p-type single crystal epitaxial silicon layer may have a thickness in the range of 15 microns to 55 microns, endpoints inclusive. Furthermore, wherein the average thickness of the as-deposited n-type single crystal epitaxial silicon FSF layer may be in the range of greater than 15 microns to less than 60 microns. Furthermore, wherein the FSF may be texture etched on a front surface. Furthermore, wherein the average thickness of the as-deposited n-type single crystal epitaxial silicon FSF layer may be in the range of greater than 15 microns to less than or equal to 55 microns. Furthermore, wherein the average thickness of the as-deposited n-type single crystal epitaxial silicon FSF layer may be in the range of 15 microns to 40 microns, endpoints inclusive. Furthermore, wherein the silicon solar cell may be bifacial. Furthermore, wherein the silicon solar cell may have textured front and back surfaces. Furthermore, wherein the FSF may have a total thickness in the range of greater than 10 microns to less than 60 microns. Furthermore, wherein the as-deposited n-type single crystal epitaxial silicon FSF layer may have an n-type dopant concentration in the range of 1.0 E17/cm³ to 1.0E18/cm³, endpoints inclusive. Furthermore, the silicon solar cell structure may further comprise selective n⁺⁺ areas on the surface of the FSF for making ohmic contact between the FSF and metal contact structures.

Some examples of PERC cell structures with a diffused FSF are provided below, See FIG. 3.

According to some embodiments, a silicon solar cell structure may comprise: an n-type single crystal epitaxial silicon layer, the n-type single crystal epitaxial silicon layer having an n-type dopant concentration in the range of intrinsic to 1.0E16/cm³, endpoints inclusive, the n-type single crystal epitaxial silicon layer having first and second surfaces; and a front surface field (FSF) on the second surface of the n-type single crystal epitaxial silicon layer, the FSF comprising a diffused layer having an n-type dopant concentration in the range of 1.0E17/cm³ to 5.0E20/cm³, endpoints inclusive; and a p⁺ emitter on the first surface of the n-type single crystal epitaxial silicon layer, the p⁺ emitter comprising as-deposited p-type single crystal epitaxial silicon contacting the first surface of the n-type single crystal epitaxial silicon layer, the as-deposited p-type single crystal epitaxial silicon having a p-type dopant concentration in the range of 1.0E16/cm³ to 5.0E18/cm³, endpoints inclusive, the p⁺ emitter further comprising a plurality of aluminum-doped p-type silicon regions, the p⁺ emitter having an average thickness (indicated by “y” in FIG. 3) of greater than 10 microns. Furthermore, wherein the FSF may be texture etched on a front surface. Furthermore, wherein the diffused layer may have a thickness in the range of 0 to 5 microns. Furthermore, wherein the as-deposited p-type single crystal epitaxial silicon may have a uniform dopant concentration in the range of 5.0E16/cm³ to 5.0E18/cm³, endpoints inclusive. Furthermore, wherein the p⁺ emitter may have a thickness in the range of 10 microns to 60 microns, endpoints inclusive. Furthermore, wherein the p⁺ emitter may have a thickness in the range of 15 microns to 55 microns, endpoints inclusive. Furthermore, wherein the silicon solar cell may be bifacial. Furthermore, wherein the silicon solar cell may have textured front and back surfaces.

Some examples of PERC cell structures with an epitaxially deposited FSF are provided below. See FIG. 4.

According to some embodiments, a silicon solar cell structure may comprise: an n-type single crystal epitaxial silicon layer, the n-type single crystal epitaxial silicon layer having an n-type dopant concentration in the range of intrinsic to 5.0E15/cm³, endpoints inclusive, the n-type single crystal epitaxial silicon layer having first and second surfaces; and a front surface field (FSF) on the second surface of the n-type single crystal epitaxial silicon layer, the FSF comprising an as-deposited n-type single crystal epitaxial silicon FSF layer contacting the second surface of the n-type single crystal epitaxial silicon layer, the as-deposited n-type single crystal epitaxial silicon FSF layer having an n-type dopant concentration in the range of 5.0E16/cm³ to 5.0E18/cm³, endpoints inclusive, the as-deposited n-type single crystal epitaxial silicon FSF layer having an average thickness (indicated by “z” in FIG. 4) of greater than 10 microns; and a p⁺ emitter on the first surface of the n-type single crystal epitaxial silicon layer. Furthermore, wherein the p⁺ emitter may comprise as-deposited p-type single crystal epitaxial silicon contacting the first surface of the n-type single crystal epitaxial silicon layer, the as-deposited p-type single crystal epitaxial silicon having a p-type dopant concentration in the range of 1.0E16/cm³ to 5.0E18/cm³, endpoints inclusive, the p⁺ emitter further comprising a plurality of aluminum-doped p-type silicon regions, the p⁺ emitter having an average thickness (indicated by “y” in FIG. 4) of greater than 10 microns, and furthermore, wherein the as-deposited p-type single crystal epitaxial silicon may have a uniform dopant concentration in the range of 5.0E16/cm³ to 5.0E18/cm³, endpoints inclusive, or wherein the p⁺ emitter may have a thickness in the range of 10 microns to 60 microns, endpoints inclusive, or furthermore, wherein the p⁺ emitter has a thickness in the range of 15 microns to 55 microns, endpoints inclusive. Furthermore, wherein the average thickness of the as-deposited n-type single crystal epitaxial silicon FSF layer may be in the range of greater than 15 microns to less than 60 microns. Furthermore, wherein the FSF may be texture etched on a front surface. Furthermore, wherein the average thickness of the as-deposited n-type single crystal epitaxial silicon FSF layer may be in the range of greater than 15 microns to less than or equal to 55 microns. Furthermore, wherein the average thickness of the as-deposited n-type single crystal epitaxial silicon FSF layer may be in the range of 15 microns to 40 microns, endpoints inclusive. Furthermore, wherein the silicon solar cell may be bifacial. Furthermore, wherein the silicon solar cell may have textured front and back surfaces. Furthermore, wherein the FSF may have a total thickness in the range of greater than 10 microns to less than 60 microns. Furthermore, wherein the as-deposited n-type single crystal epitaxial silicon FSF layer may have an n-type dopant concentration in the range of 1.0 E17/cm³ to 1.0E18/cm³, endpoints inclusive. Furthermore, the silicon solar cell structure may further comprise selective n⁺⁺ areas on the surface of the FSF for making ohmic contact between the FSF and metal contact structures.

Some examples of silicon solar cell structures, prior to back side metallization, comprising n⁺-n, n-p⁺ and n⁺-n-p⁺ wafers are provided below.

According to some embodiments, a silicon solar cell structure may comprise: a first n-type single crystal epitaxial silicon layer, the first n-type single crystal epitaxial silicon layer having an n-type dopant concentration in the range of intrinsic to 5.0E15/cm³, endpoints inclusive, the first n-type single crystal epitaxial silicon layer having first and second surfaces; and a front surface field (FSF) on the second surface of the first n-type single crystal epitaxial silicon layer, the FSF comprising a second n-type single crystal epitaxial silicon layer contacting the second surface of the first n-type single crystal epitaxial silicon layer, the second n-type single crystal epitaxial silicon layer having an n-type dopant concentration in the range of 5.0E16/cm³ to 5.0E18/cm³, endpoints inclusive, the FSF having a thickness in the range of greater than or equal to 10 microns to less than or equal to 60 microns. Furthermore, wherein the FSF may have a thickness in the range of greater than 10 microns to less than 60 microns. Furthermore, wherein an effective sheet resistance of the silicon solar cell structure, measured on the front surface of the FSF, may be in the range of 1 Ohm per square to 60 Ohms per square. Furthermore, the silicon solar cell structure may further comprise a p+ emitter on the first surface of the first n-type single crystal epitaxial silicon layer, and furthermore wherein the p⁺ emitter may comprise an epitaxially deposited p-type single crystal epitaxial silicon layer with a p-type dopant concentration in the range of 1.0E16/cm³ to 5.0E18/cm³, endpoints inclusive, the epitaxially deposited p-type single crystal epitaxial silicon layer having an average thickness in the range of greater than 10 microns to less than 70 microns, and yet furthermore, wherein the epitaxially deposited p-type single crystal epitaxial silicon layer may have an average thickness in the range of greater than 10 microns to less than 70 microns, or wherein an effective sheet resistance of the silicon solar cell structure, measured on the back surface of the epitaxially deposited p-type single crystal epitaxial silicon layer, may be in the range of 1 Ohm per square to 60 Ohms per square.

According to some embodiments, a silicon solar cell structure may comprise: a first n-type single crystal epitaxial silicon layer, the first n-type single crystal epitaxial silicon layer having an n-type dopant concentration in the range of intrinsic to 5.0E15/cm³, endpoints inclusive, the first n-type single crystal epitaxial silicon layer having first and second surfaces; and a p⁺ emitter on the first surface of the n-type single crystal epitaxial silicon layer, the p⁺ emitter comprising an epitaxially deposited p-type single crystal epitaxial silicon layer with a p-type dopant concentration in the range of 1.0E16/cm³ to 5.0E18/cm³, endpoints inclusive, the epitaxially deposited p-type single crystal epitaxial silicon layer having an average thickness in the range of greater than 10 microns to less than 70 microns. Furthermore, wherein an effective sheet resistance of the silicon solar cell structure, measured on the back surface of the epitaxially deposited p-type single crystal epitaxial silicon layer, may be in the range of 1 Ohm per square to 60 Ohms per square.

Some examples of methods of fabricating silicon solar cell structures comprising n⁺-n, n-p⁺ and n⁺-n-p⁺ wafers are provided below.

According to some embodiments, a method of fabricating a single crystal silicon solar cell structure may comprise: epitaxially depositing on a reusable single crystal silicon wafer a first n-type single crystal silicon layer having a thickness in the range of greater than 10 microns to less than 60 microns, the first n-type silicon layer having an n-type dopant concentration in the range of 5.0E16/cm³ to 5.0E18/cm³; epitaxially depositing on the first n-type single crystal silicon layer a second n-type single crystal silicon layer, the second n-type single crystal silicon layer having an n-type dopant concentration in the range of intrinsic to 5.0E15/cm³, endpoints inclusive; and separating the single crystal silicon solar cell structure from the reusable single crystal silicon wafer. Furthermore, wherein an effective sheet resistance of the single crystal silicon solar cell structure, measured on the surface of the first n-type single crystal silicon layer, may be in the range of 1 Ohm per square to 50 Ohms per square. Furthermore, wherein the first n-type single crystal silicon layer may have a thickness in the range of greater than or equal to 15 microns to less than or equal to 55 microns, and furthermore, wherein an effective sheet resistance of the single crystal silicon solar cell structure, measured on the surface of the first n-type single crystal silicon layer, may be in the range of 1 Ohm per square to 60 Ohms per square. Furthermore, the method may further comprise, before the separating, epitaxially depositing on the second n-type single crystal silicon layer a p-type single crystal silicon layer, and furthermore, wherein the p-type single crystal silicon layer may have a p-type dopant concentration in the range of 1.0E16/cm³ to 5.0E18/cm³, endpoints inclusive, the p-type single crystal silicon layer having an average thickness in the range of greater than 10 microns to less than 70 microns, and yet furthermore wherein an effective sheet resistance of the silicon solar cell structure, measured on the surface of the p-type single crystal silicon layer, is in the range of 1 Ohm per square to 60 Ohms per square.

According to some embodiments, a method of fabricating a single crystal silicon solar cell structure may comprise: epitaxially depositing on a reusable single crystal silicon wafer a first n-type single crystal silicon layer, the first n-type single crystal silicon layer having an n-type dopant concentration in the range of intrinsic to 5.0E15/cm³, endpoints inclusive; epitaxially depositing on the first n-type single crystal silicon layer, a p-type single crystal silicon layer having a p-type dopant concentration in the range of 1.0E16/cm³ to 5.0E18/cm³, endpoints inclusive, the p-type single crystal silicon layer having an average thickness in the range of greater than 10 microns to less than 70 microns; and separating the single crystal silicon solar cell structure from the reusable single crystal silicon wafer. Furthermore, wherein an effective sheet resistance of the silicon solar cell structure, measured on the surface of the p-type single crystal silicon layer, may be in the range of 1 Ohm per square to 60 Ohms per square.

According to some embodiments, a method of fabricating a single crystal silicon solar cell structure may comprise: providing an n-type silicon wafer, the wafer comprising: (1) a first n-type single crystal epitaxial silicon layer, the first n-type single crystal epitaxial silicon layer having an n-type dopant concentration in the range of intrinsic to 5.0E15/cm³, endpoints inclusive, the first n-type single crystal epitaxial silicon layer having first and second surfaces; and (2) a front surface field (FSF) on the second surface of the first n-type single crystal epitaxial silicon layer, the FSF comprising a second n-type single crystal epitaxial silicon layer contacting the second surface of the first n-type single crystal epitaxial silicon layer, the second n-type single crystal epitaxial silicon layer having an n-type dopant concentration in the range of 5.0E16/cm³ to 5.0E18/cm³, endpoints inclusive, the FSF having a thickness in the range of greater than 10 microns to less than 60 microns; and forming a p⁺ emitter on the first surface of the first n-type single crystal epitaxial silicon layer. Furthermore, wherein an effective sheet resistance of the single crystal silicon solar cell structure, measured on the surface of the FSF, may be in the range of 1 Ohm per square to 60 Ohms per square. Furthermore, wherein the second n-type single crystal epitaxial silicon layer may have a thickness in the range of greater than or equal to 15 microns to less than or equal to 55 microns, and furthermore wherein an effective sheet resistance of the single crystal silicon solar cell structure, measured on the surface of the FSF, may be in the range of 1 Ohm per square to 50 Ohms per square, and yet furthermore wherein the p⁺ emitter has an average thickness of greater than 10 microns. Furthermore the method may further comprise, depositing a dielectric layer on the p⁺ emitter and opening apertures in the dielectric layer to form a modified dielectric layer, and depositing aluminum on the modified dielectric layer and forming ohmic contacts between the aluminum and the p⁺ emitter at the positions of the apertures. Furthermore, the method may further comprise texture etching the surface of the FSF. Furthermore, the method may further comprise forming n⁺⁺ areas on the surface of the FSF for making ohmic contact between the FSF and metal contact structures. Furthermore, wherein the forming a p⁺ emitter may comprise depositing a layer of doped amorphous silicon.

According to some embodiments, a method of fabricating a single crystal silicon solar cell structure may comprise: providing a silicon wafer, the wafer comprising: (1) a first n-type single crystal epitaxial silicon layer, the first n-type single crystal epitaxial silicon layer having an n-type dopant concentration in the range of intrinsic to 5.0E15/cm³, endpoints inclusive, the first n-type single crystal epitaxial silicon layer having first and second surfaces; (2) a front surface field (FSF) on the second surface of the first n-type single crystal epitaxial silicon layer, the FSF comprising a second n-type single crystal epitaxial silicon layer contacting the second surface of the first n-type single crystal epitaxial silicon layer, the second n-type single crystal epitaxial silicon layer having an n-type dopant concentration in the range of 5.0E16/cm³ to 5.0E18/cm³, endpoints inclusive, the FSF having a thickness in the range of greater than 10 microns to less than 60 microns; and (3) a p⁺ emitter on the first surface of the first n-type single crystal epitaxial silicon layer, the p⁺ emitter comprising an epitaxially deposited p-type single crystal epitaxial silicon layer with a p-type dopant concentration in the range of 1.0E16/cm³ to 5.0E18/cm³, endpoints inclusive, the epitaxially deposited p-type single crystal epitaxial silicon layer having an average thickness in the range of greater than 10 microns to less than 70 microns; and forming n⁺⁺ areas on the surface of the FSF for making ohmic contact between the FSF and metal contact structures. Furthermore, wherein the second n-type single crystal epitaxial silicon layer may have a thickness in the range of greater than or equal to 15 microns to less than or equal to 55 microns. Furthermore, the method may further comprise, depositing a dielectric layer on the p⁺ emitter and opening apertures in the dielectric layer to form a modified dielectric layer, and depositing aluminum on the modified dielectric layer and forming ohmic contacts between the aluminum and the p⁺ emitter at the positions of the apertures. Furthermore, the method may further comprise, before the forming n⁺⁺ areas, texture etching the surface of the FSF. Furthermore, the method may further comprise depositing aluminum on the back surface of the p⁺ emitter and forming at least one ohmic contact between the aluminum and the p⁺ emitter.

According to some embodiments, a method of fabricating a single crystal silicon solar cell structure may comprise: providing a silicon wafer, the wafer comprising: (1) a first n-type single crystal epitaxial silicon layer, the first n-type single crystal epitaxial silicon layer having an n-type dopant concentration in the range of intrinsic to 5.0E15/cm³, endpoints inclusive, the first n-type single crystal epitaxial silicon layer having first and second surfaces; and (2) a p⁺ emitter on the first surface of the first n-type single crystal epitaxial silicon layer, the p⁺ emitter comprising an epitaxially deposited p-type single crystal epitaxial silicon layer with a p-type dopant concentration in the range of 1.0E16/cm³ to 5.0E18/cm³, endpoints inclusive, the epitaxially deposited p-type single crystal epitaxial silicon layer having an average thickness in the range of greater than 10 microns to less than 70 microns; and forming a front surface field (FSF) on the second surface of the first n-type single crystal epitaxial silicon layer. Furthermore, wherein the FSF may comprise a diffused layer having an n-type dopant concentration in the range of 1.0E17/cm³ to 5.0E20/cm³, endpoints inclusive, and furthermore wherein the diffused layer may have a thickness in the range of 0 to 5 microns. Furthermore, the method may further comprise forming selective n⁺⁺ areas on the surface of the FSF for making ohmic contact between the FSF and metal contact structures. Furthermore, the method may further comprise, depositing a dielectric layer on the p⁺ emitter and opening apertures in the dielectric layer to form a modified dielectric layer, and depositing aluminum on the modified dielectric layer and forming ohmic contacts between the aluminum and the p⁺ emitter at the positions of the apertures. Furthermore, the method may further comprise depositing aluminum on the back surface of the p⁺ emitter and forming at least one ohmic contact between the aluminum and the p⁺ emitter.

Although the present invention has been particularly described with reference to certain embodiments thereof, it should be readily apparent to those of ordinary skill in the art that changes and modifications in the form and details may be made without departing from the spirit and scope of the invention.

1. A silicon solar cell structure comprising:
an n-type single crystal epitaxial silicon layer, said n-type single crystal epitaxial silicon layer having an n-type dopant concentration in the range of intrinsic to 1.0E16/cm³, endpoints inclusive, said n-type single crystal epitaxial silicon layer having first and second surfaces; and
a front surface field (FSF) on said second surface of said n-type single crystal epitaxial silicon layer, said FSF comprising a diffused layer having an n-type dopant concentration in the range of 1.0E17/cm³ to 5.0E20/cm³, endpoints inclusive, wherein said diffused layer has a thickness in the range of 0 to 5 microns; and
a p⁺ emitter on said first surface of said n-type single crystal epitaxial silicon layer, said p⁺ emitter comprising an as-deposited p-type single crystal epitaxial silicon layer with a p-type dopant concentration in the range of 1.0E16/cm³ to 5.0E18/cm³, endpoints inclusive, said p⁺ emitter further comprising an aluminum-doped p-type single crystal epitaxial silicon layer separated from said first surface by said as-deposited p-type single crystal epitaxial silicon layer, said as-deposited p-type single crystal epitaxial silicon layer having an average thickness in the range of 10 microns to 60 microns, endpoints inclusive.

2. The silicon cell structure as in claim 1, wherein said FSF is texture etched on a front surface.

3. (canceled)

4. The silicon solar cell structure as in claim 1, wherein said as-deposited p-type single crystal epitaxial silicon layer has a uniform dopant concentration in the range of 5.0E16/cm³ to 5.0E18/cm³, endpoints inclusive.

5. (canceled)

6. The silicon solar cell structure as in claim 1, wherein said as-deposited p-type single crystal epitaxial silicon layer has a thickness in the range of 15 microns to 55 microns, endpoints inclusive.

7. The silicon solar cell structure as in claim 1, wherein said silicon solar cell is bifacial.

8. The silicon solar cell structure as in claim 1, wherein said silicon solar cell has textured front and back surfaces.

9. A silicon solar cell structure comprising:
an n-type single crystal epitaxial silicon layer, said n-type single crystal epitaxial silicon layer having an n-type dopant concentration in the range of intrinsic to 1.0E16/cm³, endpoints inclusive, said n-type single crystal epitaxial silicon layer having first and second surfaces; and
a front surface field (FSF) on said second surface of said n-type single crystal epitaxial silicon layer, said FSF comprising an as-deposited n-type single crystal epitaxial silicon FSF layer contacting said second surface of said n-type single crystal epitaxial silicon layer, said as-deposited n-type single crystal epitaxial silicon FSF layer having an n-type dopant concentration in the range of 5.0E16/cm³ to 5.0E18/cm³, endpoints inclusive, said as-deposited n-type single crystal epitaxial silicon FSF layer having an average thickness of greater than 10 microns; and
a p⁺ emitter on said first surface of said n-type single crystal epitaxial silicon layer.

10. (canceled)

11. The silicon solar cell structure as in claim 9, wherein said average thickness of said as-deposited n-type single crystal epitaxial silicon FSF layer is in the range of greater than 15 microns to less than 60 microns.

12. The silicon solar cell structure as in claim 9, wherein said FSF is texture etched on a front surface.

13. The silicon solar cell structure as in claim 9, wherein said average thickness of said as-deposited n-type single crystal epitaxial silicon FSF layer is in the range of greater than 15 microns to less than or equal to 55 microns.

14. The silicon solar cell structure as in claim 9, wherein said average thickness of said as-deposited n-type single crystal epitaxial silicon FSF layer is in the range of 15 microns to 40 microns, endpoints inclusive.

15-17. (canceled)

18. The silicon solar cell structure as in claim 9, wherein said silicon solar cell is bifacial.

19. The silicon solar cell structure as in claim 9, wherein said silicon solar cell has textured front and back surfaces.

20. The silicon solar cell structure as in claim 9, wherein said FSF has a total thickness in the range of greater than 10 microns to less than 60 microns.

21. The silicon solar cell structure as in claim 9, wherein said as-deposited n-type single crystal epitaxial silicon FSF layer has an n-type dopant concentration in the range of 1.0 E17/cm³ to 1.0E18/cm³, endpoints inclusive.

22. The silicon solar cell structure as in claim 9, further comprising selective n⁻⁺ areas on the surface of said FSF for making ohmic contact between said FSF and metal contact structures.

23-71. (canceled)

72. A method of fabricating a single crystal silicon solar cell structure comprising: providing a silicon wafer, said wafer comprising:
a first n-type single crystal epitaxial silicon layer, said first n-type single crystal epitaxial silicon layer having an n-type dopant concentration in the range of intrinsic to 5.0E15/cm³, endpoints inclusive, said first n-type single crystal epitaxial silicon layer having first and second surfaces;
a front surface field (FSF) on said second surface of said first n-type single crystal epitaxial silicon layer, said FSF comprising a second n-type single crystal epitaxial silicon layer contacting said second surface of said first n-type single crystal epitaxial silicon layer, said second n-type single crystal epitaxial silicon layer having an n-type dopant concentration in the range of 5.0E16/cm³ to 5.0E18/cm³, endpoints inclusive, said FSF having a thickness in the range of greater than 10 microns to less than 60 microns; and
a p⁺ emitter on said first surface of said first n-type single crystal epitaxial silicon layer, said p⁺ emitter comprising an epitaxially deposited p-type single crystal epitaxial silicon layer with a p-type dopant concentration in the range of 1.0E16/cm³ to 5.0E18/cm³, endpoints inclusive, said epitaxially deposited p-type single crystal epitaxial silicon layer having an average thickness in the range of greater than 10 microns to less than 70 microns; and
forming n⁺⁺ areas on the surface of said FSF for making ohmic contact between said FSF and metal contact structures.

73. The method of fabricating a single crystal silicon solar cell structure as in claim 72, wherein said second n-type single crystal epitaxial silicon layer has a thickness in the range of greater than or equal to 15 microns to less than or equal to 55 microns.

74. The method of fabricating a silicon solar cell structure as in claim 72, further comprising, depositing a dielectric layer on said p⁺ emitter and opening apertures in said dielectric layer to form a modified dielectric layer, and depositing aluminum on said modified dielectric layer and forming ohmic contacts between said aluminum and said p⁺ emitter at the positions of said apertures.

75. The method of fabricating a silicon solar cell structure as in claim 72, further comprising, before said forming n++ areas, texture etching the surface of said FSF.

76. The method of fabricating a single crystal silicon solar cell structure as in claim 72, further comprising depositing aluminum on the back surface of said p⁺ emitter and forming at least one ohmic contact between said aluminum and said p⁺ emitter.

77. A method of fabricating a single crystal silicon solar cell structure comprising: providing a silicon wafer, said wafer comprising:
a first n-type single crystal epitaxial silicon layer, said first n-type single crystal epitaxial silicon layer having an n-type dopant concentration in the range of intrinsic to 5. 0E15/cm³, endpoints inclusive, said first n-type single crystal epitaxial silicon layer having first and second surfaces; and
a p⁺ emitter on said first surface of said first n-type single crystal epitaxial silicon layer, said p⁺ emitter comprising an epitaxially deposited p-type single crystal epitaxial silicon layer with a p-type dopant concentration in the range of 1.0E16/cm³ to 5.0E18/cm³, endpoints inclusive, said epitaxially deposited p-type single crystal epitaxial silicon layer having an average thickness in the range of greater than 10 microns to less than 70 microns; and
forming a front surface field (FSF) on said second surface of said first n-type single crystal epitaxial silicon layer.

78. The method of fabricating a single crystal silicon solar cell structure as in claim 77, wherein said FSF comprises a diffused layer having an n-type dopant concentration in the range of 1.0E17/cm³ to 5.0E20/cm³, endpoints inclusive, and a thickness in the range of 0 to 5 microns.

79. (canceled)

80. The method of fabricating a single crystal silicon solar cell structure as in claim 77, further comprising forming selective n⁺⁺ areas on the surface of said FSF for making ohmic contact between said FSF and metal contact structures.

81. The method of fabricating a silicon solar cell structure as in claim 77, further comprising, depositing a dielectric layer on said p⁺ emitter and opening apertures in said dielectric layer to form a modified dielectric layer, and depositing aluminum on said modified dielectric layer and forming ohmic contacts between said aluminum and said p emitter at the positions of said apertures.

82. The method of fabricating a single crystal silicon solar cell structure as in claim 77, further comprising depositing aluminum on the back surface of said p⁺ emitter and forming at least one ohmic contact between said aluminum and said p⁺ emitter.
